(19) United States
(12) Patent Application Publication
(10) Pub. No.: US 2024/0395754 A1
(43) Pub. Date: Nov. 28, 2024

(54) SEMICONDUCTOR DEVICE, SEMICONDUCTOR MODULE, AND METHOD FOR MANUFACTURING SEMICONDUCTOR DEVICE

(71) Applicant: SUMITOMO ELECTRIC INDUSTRIES, LTD., Osaka (JP)

(72) Inventors: Yutaka MORIYAMA, Osaka (JP); Tatsuya HASHINAGA, Osaka (JP)

(21) Appl. No.: 18/664,852

(22) Filed: May 15, 2024

(30) Foreign Application Priority Data
May 25, 2023 (JP) 2023-086382
Apr. 2, 2024 (JP) 2024-059490

(51) Int. Cl. H01L 23/00; H01L 23/31

(52) U.S. Cl. CPC H01L 24/13; H01L 23/3114; H01L 24/05; H01L 24/32; H01L 24/73; H01L 2224/0401; H01L 2224/13082; H01L 2224/32245; H01L 2224/73253

(57) ABSTRACT

A semiconductor device includes a substrate having a first main surface and a second main surface opposite the first main surface. The semiconductor device includes a gate pad and a drain pad provided on the first main surface, and includes a source pad provided on the second main surface. The semiconductor device includes a first bump provided on the gate pad, the first bump including a plurality of first stud bumps stacked over one another. The semiconductor device includes a second bump provided on the drain pad, the second bump including a plurality of second stud bumps stacked over one another. The semiconductor device includes an insulating resin layer provided around the first bump and the second bump.

### CROSS-REFERENCE TO RELATED APPLICATIONS

This application claims priority of Japanese Patent Applications Nos. 2023-86382, filed on May 25, 2023, and 2024-59490, filed on Apr. 2, 2024, the entire contents of which are incorporated herein by reference.

### TECHNICAL FIELD

The present disclosure relates to a semiconductor device, a semiconductor module, and a method for manufacturing a semiconductor device.

### BACKGROUND

Semiconductor devices in which semiconductor chips of transistors are mounted on lead frames have been used. In such a semiconductor device, electrodes of the transistor are connected to a lead by bonding wires, and sealed with a mold resin.

### CITATION LIST

### Patent Documents

[Patent Document 1] Japanese Unexamined Patent Application Publication No. 2006-108408
[Patent Document 2] Japanese Unexamined Utility Model Application Publication No. H5-046031
[Patent Document 3] Japanese Unexamined Patent Application Publication No. 2003-273148
[Patent Document 4] WO2013/047520
[Patent Document 5] Japanese Unexamined Patent Application Publication No. 2016-100408
[Patent Document 6] Japanese Unexamined Patent Application Publication No. 2006-216770

### SUMMARY

A semiconductor device in the present disclosure includes a substrate having a first main surface and a second main surface opposite the first main surface, a gate pad provided on the first main surface, a drain pad provided on the first main surface, a source pad provided on the second main surface, a first bump provided on the gate pad, and including a plurality of first stud bumps that are stacked on each other, a second bump provided on the drain pad, and including a plurality of second stud bumps that are stacked on each other, and an insulating resin layer provided around the first bump and the second bump.

### BRIEF DESCRIPTION OF THE DRAWINGS

FIG. 1 is a diagram showing the layout of a gate electrode, a source electrode, and a drain electrode in a semiconductor device according to a first embodiment.

FIG. 2 is a cross-sectional view showing the semiconductor device according to the first embodiment.

FIG. 3 is a sectional view (first part) showing a method for manufacturing the semiconductor device according to the first embodiment.

FIG. 4 is a sectional view (second part) showing the method for manufacturing the semiconductor device according to the first embodiment.

FIG. 5 is a sectional view (third part) showing the method for manufacturing the semiconductor device according to the first embodiment.

FIG. 6 is a sectional view (fourth part) showing the method for manufacturing the semiconductor device according to the first embodiment.

FIG. 7 is a cross-sectional view (fifth part) showing the method for manufacturing the semiconductor device according to the first embodiment.

FIG. 8 is a sectional view (sixth part) showing the method for manufacturing the semiconductor device according to the first embodiment.

FIG. 9 is a cross-sectional view showing an example of using the semiconductor device according to the first embodiment.

FIG. 10 is a cross-sectional view showing the semiconductor device according to a second embodiment.

FIG. 11 is a sectional view (first part) showing a method for manufacturing the semiconductor device according to the second embodiment.

FIG. 12 is a sectional view (second part) showing the method for manufacturing the semiconductor device according to the second embodiment.

FIG. 13 is a sectional view (third part) showing the method for manufacturing the semiconductor device according to the second embodiment.

FIG. 14 is a sectional view (fourth part) showing the method for manufacturing the semiconductor device according to the second embodiment.

FIG. 15 is a cross-sectional view (fifth part) showing the method for manufacturing the semiconductor device according to the second embodiment.

FIG. 16 is a sectional view (sixth part) showing the method for manufacturing the semiconductor device according to the second embodiment.

FIG. 17 is a sectional view (seventh part) showing the method for manufacturing the semiconductor device according to the second embodiment.

FIG. 18 is a cross-sectional view showing a semiconductor module according to a third embodiment.

FIG. 19 is a sectional view (first part) showing a method for manufacturing the semiconductor module according to the third embodiment.

FIG. 20 is a sectional view (second part) showing the method for manufacturing the semiconductor module according to the third embodiment.

FIG. 21 is a sectional view (third part) showing the method for manufacturing the semiconductor module according to the third embodiment.

FIG. 22 is a sectional view (fourth part) showing the method for manufacturing the semiconductor module according to the third embodiment.

FIG. 23 is a sectional view (fifth part) showing the method for manufacturing the semiconductor module according to the third embodiment.

FIG. 24 is a cross-sectional view showing the semiconductor module according to a fourth embodiment.

### DETAILED DESCRIPTION

### Problem to be Solved by the Present Disclosure

In base stations or the like for mobile phone communications, a large number of transistors are provided in one module. In such a situation, there is an increasing need for smaller sizes of semiconductor devices.

An object of the present disclosure is to provide a semiconductor device and a method for manufacturing the semiconductor device that is capable of being made compact.

### Effects of the Present Disclosure

In the present disclosure, a semiconductor device can be made compact.

### DESCRIPTION OF EMBODIMENTS OF THE PRESENT DISCLOSURE

First, embodiments of the present disclosure will be listed and described as follows.

[1] A semiconductor device in one aspect of the present disclosure includes a substrate having a first main surface and a second main surface opposite the first main surface, a gate pad provided on the first main surface, a drain pad provided on the first main surface, a source pad provided on the second main surface, a first bump provided on the gate pad and including a plurality of first stud bumps stacked over one another other, a second bump provided on the drain pad and including a plurality of second stud bumps stacked over one another, and an insulating resin layer provided around the first bump and the second bump.

A first bump includes a plurality of first stud bumps and a second bump includes a plurality of second stud bumps. With this arrangement, the need for leads is eliminated, and a semiconductor device can be made compact while adjusting the thickness of the semiconductor device.

[2] In [1], a first bump may have a first surface in contact with a gate pad and a second surface opposite a first surface, a second bump may have a third surface in contact with a drain pad and a fourth surface opposite the third surface, and an insulating resin layer may have a fifth surface that is continuous with the second surface and the fourth surface. In this case, a space between the first bump and the insulating resin layer is hardly formed, and a space between the second bump and the insulating resin layer is hardly formed.

[3] In [2], a second surface, a fourth surface, and a fifth surface may be flush with one another. The second surface, the fourth surface, and the fifth surface can be made flush with one another by grinding.

[4] In [2] or [3], a semiconductor device may further include a first solder ball provided on a second surface and a second solder ball provided on a fourth surface. In this case, the semiconductor device is easily electrically coupled to any other member via a first solder ball and a second solder ball.

[5] In any one of [2] through [4], a second surface and a fourth surface may have an arithmetic mean roughness of greater than or equal to 0.03 μm and less than or equal to 0.10 μm. The arithmetic mean roughness of each of a second surface and the fourth surface can be set to greater than or equal to 0.03 μm and less than or equal to 0.10 μm.

[6] In any one of [1] through [5], a semiconductor device may further include a metal plate bonded to a source pad, the metal plate being electrically coupled to the source pad. In this case, a potential can be applied to the source pad using a surface opposite a surface on which a first bump and a second bump are provided.

[7] In any one of [1] through [6], a substrate may include a nitride semiconductor layer. In this case, a semiconductor device is easier to operate at a high frequency.

[8] A semiconductor module in another aspect of the present disclosure includes an insulating layer having a third main surface and a fourth main surface opposite the third main surface; a wiring layer including a first wiring and a second wiring, and being provided on the third main surface of the insulating layer; a semiconductor device in any one of [1] through [7], the semiconductor device being provided in the insulating layer and being coupled to the first wiring; and an electronic component provided in the insulating layer and being coupled to the second wiring. The semiconductor device includes a conductive material electrically coupled to a source pad, the conductor material being exposed from the fourth main surface of the insulating layer. A semiconductor module with a semiconductor device in any one of [1] through [7] is obtained.

[9] In [8], a first thickness of a substrate may be less than a second thickness of an electronic component. Even when the first thickness is less than the second thickness, a conductive material can be exposed from a fourth main surface by adjusting thicknesses of first stud bumps and second stud bumps.

[10] In [8] or [9], a conductive material may have a sixth surface flush with a fourth main surface. The fourth main surface can be made flush with the sixth surface by grinding.

[11] In any one of [8] through [10], a semiconductor module includes a conductive layer provided on a fourth main surface of an insulating layer, and being in contact with a conductive material, and a conductive layer and an electronic component may be separated from each other by an insulating layer. In this case, the conductive layer is in contact with the conductive material while the electronic component is separated from the conductive layer.

[12] A method for manufacturing a semiconductor device in another aspect of the present disclosure includes providing a semiconductor chip including a substrate, a gate pad, a drain pad, and a source pad, the semiconductor chip including the substrate having a first main surface and a second main surface opposite the first main surface, the gate pad and the drain pad that are provided on the first main surface, and the source pad provided on the second main surface; forming a first bump on the gate pad; forming a second bump on the drain pad; forming an insulating resin layer around the first bump and the second bump; and grinding the insulating resin layer, the first bump, and the second bump. The first bump includes a plurality of first stud bumps stacked over one another, and the second bump includes a plurality of second stud bumps stacked over one another.

With this approach, the first bump includes a plurality of first stud bumps, and a second bump includes a plurality of second stud bumps. In such a situation, the need for leads is eliminated, and a semiconductor device can be made compact while adjusting a thickness of the semiconductor device.

### Details of Embodiments of the Present Disclosure

Hereinafter, embodiments of the present disclosure will be described in detail, but the present disclosure is not limited to the embodiments. In the present specification and the drawings, for components having substantially the same functional configuration, the same numerals may denote these components and redundant description may be omitted. In the following description, an XYZ-orthogonal coordinate system is used, but the coordinate system is defined for the purpose of description and does not limit a posture of the semiconductor device. Further, when viewed from any point, a positive Z-side may be referred to as an upper direction, an upper side, or a top, and a negative Z-side may be referred to as a lower direction, a lower side, or a bottom.

### First Embodiment

A first embodiment is described below. The first embodiment relates to a semiconductor device including a GaN-based HEMT (high electron mobility transistor).

### [Configuration of Semiconductor Device]

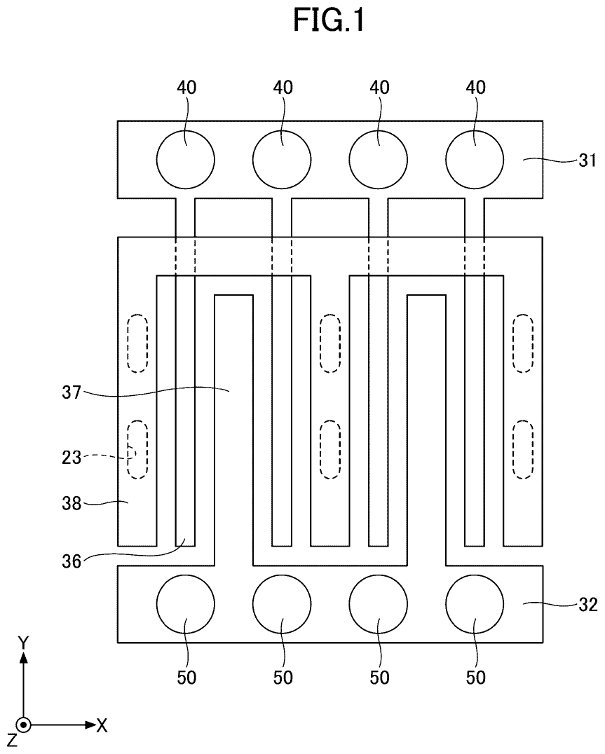

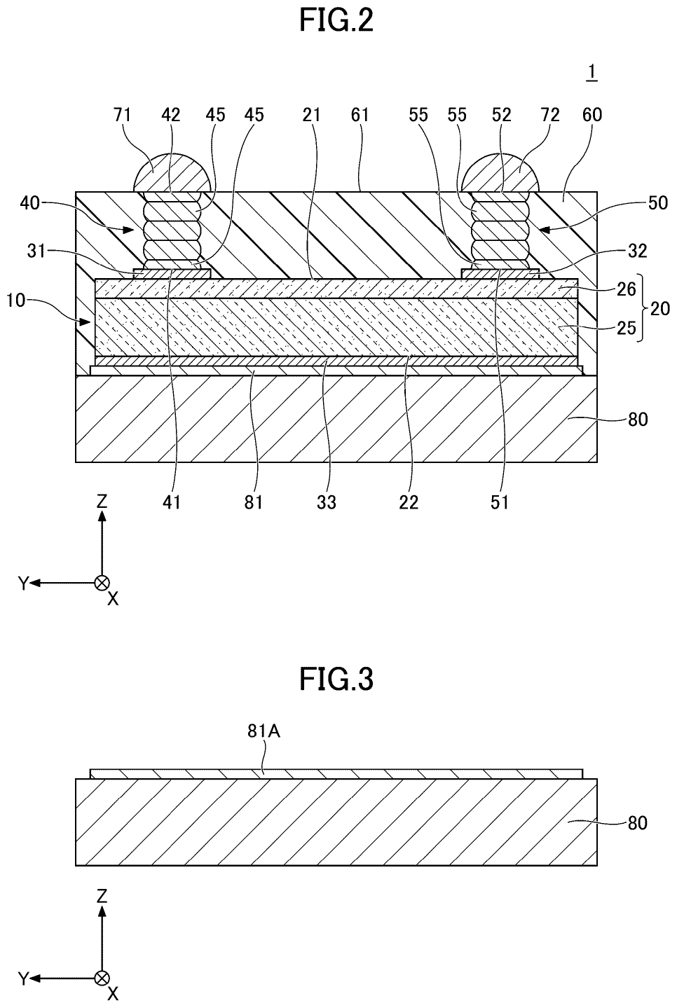

The configuration of the semiconductor device according to the first embodiment will be described below. FIG. 1 is a diagram showing the layout of a gate electrode, a source electrode, and a drain electrode in the semiconductor device according to the first embodiment. FIG. 2 is a cross-sectional view showing the semiconductor device according to the first embodiment.

As shown in FIGS. 1 and 2, the semiconductor device 1 according to the first embodiment mainly includes a metal plate 80, a semiconductor chip 10, a first bump 40, a second bump 50, an insulating resin layer 60, a first solder ball 71, and a second solder ball 72.

The semiconductor chip 10 includes a substrate 20, a gate pad 31, a drain pad 32, a source pad 33, multiple gate electrodes 36, multiple drain electrodes 37, and multiple source electrodes 38. The substrate 20 includes a semiconductor substrate 25 and a semiconductor layer 26. The thickness of the substrate 20 is, for example, greater than or equal to 50 μm and less than or equal to 200 μm. The semiconductor substrate 25 is, for example, a silicon carbide (SiC) substrate. The semiconductor layer 26 is provided on the semiconductor substrate 25. The semiconductor layer 26 is, for example, a nitride semiconductor layer that contains gallium (Ga). The nitride semiconductor layer constitutes part of a high electron mobility transistor that includes an electron transit layer (channel layer), an electron supply layer (barrier layer), and the like. A two-dimensional gas (2DEG) exists in the semiconductor layer 26, and a portion where the 2DEG exists functions as a channel. The substrate 20 has a first main surface 21 and a second main surface 22 opposite the first main surface 21. The semiconductor layer 26 has the first main surface 21, and the semiconductor substrate 25 has the second main surface 22. The first main surface 21 is an upper surface of the substrate 20, and the second main surface 22 is a lower surface of the substrate 20.

The gate electrodes 36, the drain electrodes 37, and the source electrodes 38 are provided on the first main surface 21. The drain electrodes 37 and the source electrodes 38 extend parallel to the Y-axis direction, and the drain electrode 37 and the source electrode 38 are alternately provided in the X-axis direction. The gate electrodes 36 extend parallel to the Y-axis direction, and each of the gate electrodes 36 is provided between the drain electrode 37 and the source electrode 38 that are next to each other in the X-axis direction.

The gate pad 31 and the drain pad 32 are provided on the first main surface 21, and the source pad 33 is provided on the second main surface 22. The gate electrodes 36 are electrically coupled to the gate pad 31, and the drain electrodes 37 are electrically coupled to the drain pad 32. Multiple through-holes 23 that extend to the respective source electrodes 38 are formed in the substrate 20, and the source electrodes 38 are electrically commonly coupled to the source pad 33 through conductors that are disposed in the through-holes 23.

The semiconductor chip 10 is fixed on the metal plate 80 by a conductive adhesive 81. The metal plate 80 is, for example, a copper (Cu) plate. The thickness of the metal plate 80 is, for example, greater than or equal to 50 μm and less than or equal to 200 μm. The conductive adhesive 81 is, for example, a sintered silver (Ag) layer. The source pad 33 is in direct contact with the conductive adhesive 81. The potential at each source electrode 38 is equal to the potential at the metal plate 80. For example, when the metal plate 80 is grounded, the source electrode 38 comes to be a ground potential.

The first bump 40 is provided on the gate pad 31. The first bump 40 includes a plurality of first stud bumps 45 that are stacked over one another. The first bump 40 has a first surface 41 in contact with the gate pad, and has a second surface 42 opposite the first surface 41. The first surface 41 is a lower surface of the first bump 40, and the second surface 42 is an upper surface of the first bump 40.

The second bump 50 is provided on the drain pad 32. The second bump 50 includes a plurality of second stud bumps 55 that are stacked over one another. The second bump 50 has a third surface 51 in contact with the drain pad, and has a fourth surface 52 opposite the third surface 51. The third surface 51 is a lower surface of the second bump 50, and the fourth surface 52 is an upper surface of the second bump 50.

The material of the first stud bump 45 and the second stud bump 55 includes, for example, gold (Au), silver (Ag), or copper (Cu). The use of Ag or Cu can reduce the cost, compared to a case of using Au. The height of each of the first bump 40 and the second bump 50 is, for example, greater than or equal to 50 μm and less than or equal to 300 μm.

The insulating resin layer 60 is provided around the first bump 40 and the second bump 50. The insulating resin layer 60 has a fifth surface 61 that is continuous with the second surface 42 of the first bump 40 and the fourth surface 52 of the second bump 50. The fifth surface 61 may be flush with the second surface 42 and the fourth surface 52. The insulating resin layer 60 covers multiple side surfaces of the first bump 40 and the second bump 50. The insulating resin layer 60 covers the first main surface 21 of the substrate 20. The insulating resin layer 60 may further cover a side surface of the substrate 20.

The first solder ball 71 is provided on the second surface 42 of the first bump 40. The first solder ball 71 is electrically connected to the first bump 40. A portion of the first solder ball 71 may be in contact with the fifth surface 61 of the insulating resin layer 60. The second solder ball 72 is provided on the fourth surface 52 of the second bump 50. The second solder ball 72 is electrically connected to the second bump 50. A portion of the second solder ball 72 may be in contact with the fifth surface 61 of the insulating resin layer 60. The insulating resin layer 60 may be in contact with the metal plate 80 around the semiconductor chip 10. That is, the semiconductor chip 10 may be sealed with the insulating resin layer 60.

With this arrangement, the semiconductor device 1 has a chip size package (CSP) structure.

### [Method for Manufacturing Semiconductor Device]

Hereinafter, a method for manufacturing the semiconductor device 1 according to the first embodiment will be described. FIGS. 3 to 8 are cross-sectional views showing the method for manufacturing the semiconductor device according to the first embodiment.

First, as shown in FIG. 3, Ag paste 81A is applied to the upper surface of the metal plate 80.

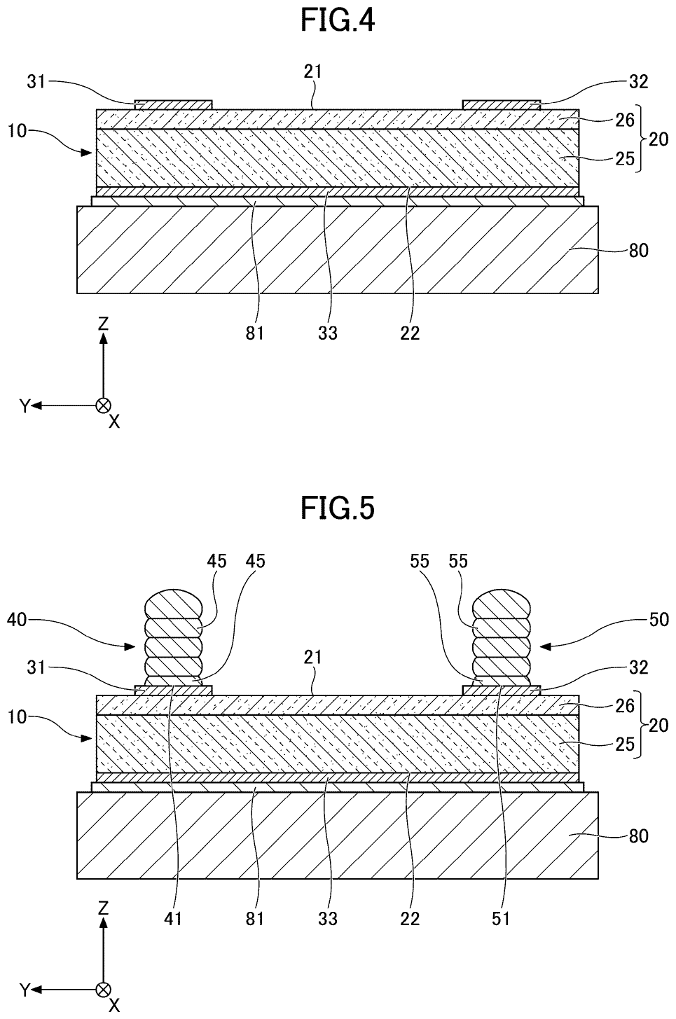

Next, as shown in FIG. 4, the semiconductor chip 10 is placed on the metal plate 80 such that the source pad 33 is in contact with the Ag paste 81A. Then, the Ag paste 81A is baked to thereby form a conductive adhesive 81 from the Ag paste 81A. The semiconductor chip 10 is fixed to the metal plate 80 through the conductive adhesive 81.

Next, as shown in FIG. 5, the first bump 40 is formed on the gate pad 31 on the semiconductor chip 10, and the second bump 50 is formed on the drain pad 32. In the forming of the first bump 40, first stud bumps 45 are stacked over the gate pad 31, and in the forming of the second bump 50, second stud bumps 55 are stacked over the drain pad 32. With this approach, the first bump 40 and the second bump 50 are each formed to be higher than a final height. The first bump 40 has the first surface 41 in contact with the gate pad 31, and the second bump 50 has the third surface 51 in contact with the drain pad 32.

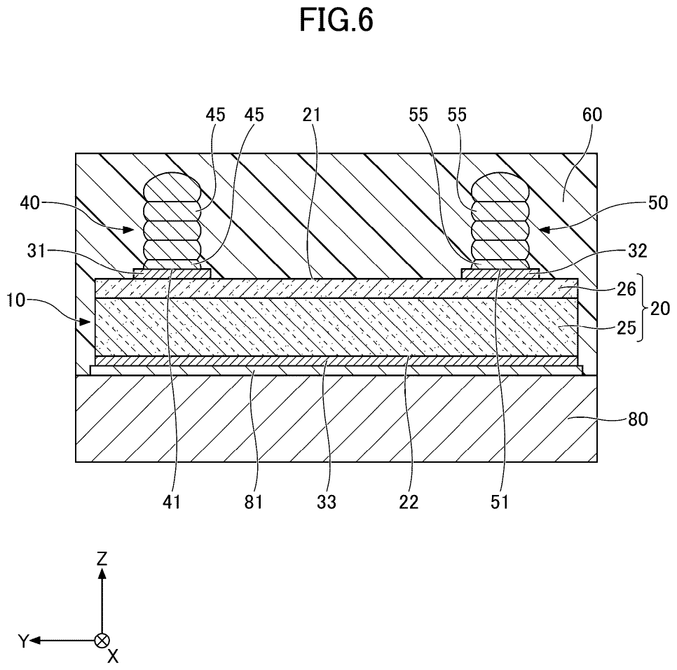

Next, as shown in FIG. 6, the insulating resin layer 60 is formed so as to cover the semiconductor chip 10, the first bump 40, and the second bump 50. For example, Ajinomoto Build-up Film (registered trademark) can be used to form the insulating resin layer 60. With this approach, the insulating resin layer 60 is formed to be thicker than a final thickness.

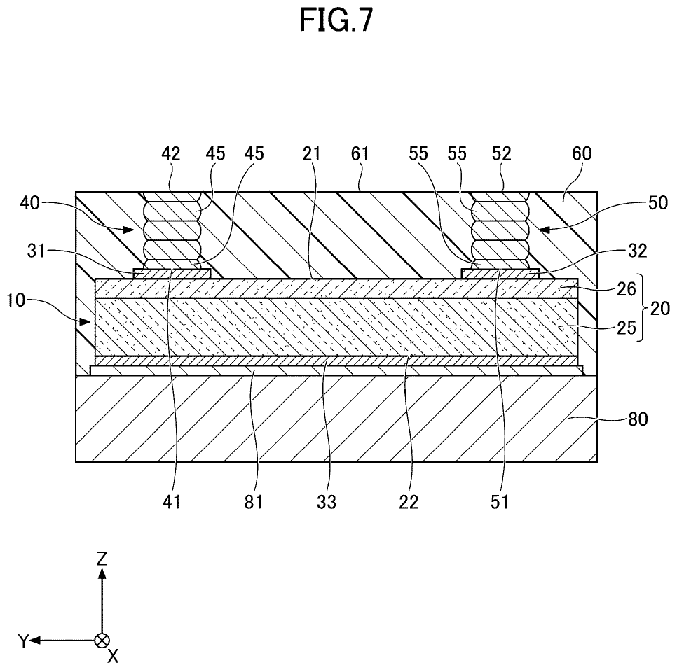

Next, as shown in FIG. 7, the insulating resin layer 60, the first bump 40, and the second bump 50 are grinded so that the resulting heights of the first bump 40 and the second bump 50 are used as final heights, and so that the resulting thickness of the insulating resin layer 60 is used as a final thickness. The fifth surface 61 of the insulating resin layer 60 may be flush with the second surface 42 of the first bump 40 and the fourth surface 52 of the second bump 50. In the grinding, for example, a grindstone having a grit size of #2000 may be used. After the grinding, the first bump 40 has the second surface 42 opposite the first surface 41, and the second bump 50 has the fourth surface 52 opposite the third surface 51. The arithmetic mean roughness (Ra) of the second surface 42 and the fourth surface 52 is, for example, greater than or equal to 0.03 μm and less than or equal to 0.10 μm. The arithmetic mean roughness of the second surface 42 and the fourth surface 52 may be greater than or equal to 0.04 μm and less than or equal to 0.09 μm, or may be greater than or equal to 0.05 μm and less than or equal to 0.08 μm.

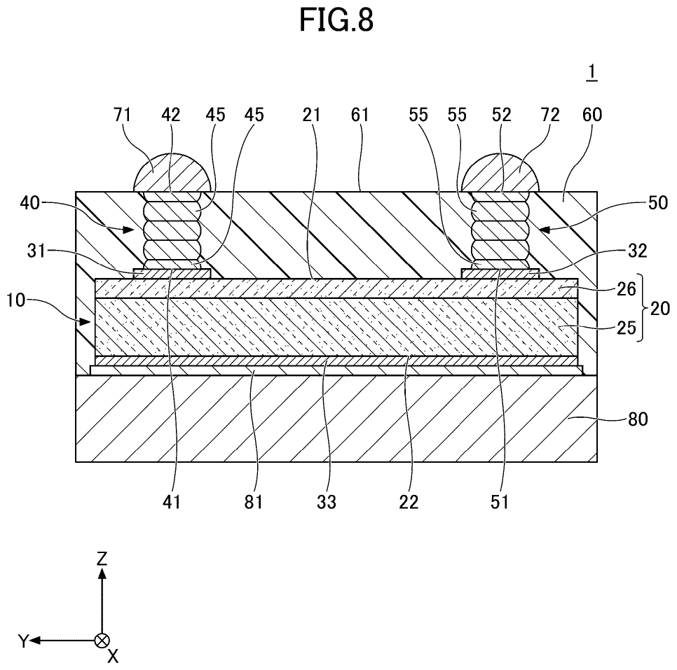

Next, as shown in FIG. 8, the first solder ball 71 is formed on the insulating resin layer 60 so as to be in contact with the second surface 42 of the first bump 40, and the second solder ball 72 is formed on the insulating resin layer 60 so as to be in contact with the fourth surface 52 of the second bump 50.

With this approach, the semiconductor device 1 according to the first embodiment can be manufactured.

In the semiconductor device 1 according to the first embodiment, both the first solder ball 71 coupled to the gate electrodes 36 and the second solder ball 72 coupled to the drain electrodes 37 are provided on the upper surface of the semiconductor device 1, and the metal plate 80 coupled to the source electrodes 38 is provided on the lower surface of the semiconductor device 1. With this arrangement, the need for leads is eliminated, and the semiconductor device 1 can be made compact.

The sizes (diameter and height) of the first bump 40 and the second bump 50 are more easily stabilized than the sizes (diameter and length) of a bonding wire. With this arrangement, the impedance of the first bump 40 and the second bump 50 is more easily adjusted. Therefore, stable electrical characteristics can be obtained.

The side surface of the first bump 40 and the side surface of the second bump 50 are covered with the insulating resin layer 60. With this arrangement, even if the first solder ball 71 and the second solder ball 72 are melted during reflow, the molten solder can be prevented from reaching the semiconductor chip 10. Thus, a short circuit or the like caused by the molten solder reaching the semiconductor chip 10 can be suppressed. The insulating resin layer 60 has the fifth surface 61 that is continuous with the second surface 42 and the fourth surface 52. In this case, a space between the first bump 40 and the insulating resin layer 60 is hardly formed, and a space between the second bump 50 and the insulating resin layer 60 is hardly formed.

The first solder ball 71 is provided on the second surface 42, and the second solder ball 72 is provided on the fourth surface 52. With this arrangement, the semiconductor device 1 is easily electrically coupled to any other member such as a mounting substrate, via the first solder ball 71 and the second solder ball 72.

The metal plate 80 that is bonded to, and electrically coupled to the source pad 33 is provided, and thus a potential such as a ground potential can be applied to the source pad 33 via a surface opposite the first bump 40 and the second bump 50.

By including the nitride semiconductor layer in the substrate 20, the semiconductor device 1 easily operates at a high frequency. In addition, the semiconductor device 1 can provide a high breakdown voltage.

Even when a thin semiconductor chip 10 is used, the semiconductor device 1 can be made thick in accordance with the heights of the first bump 40 and the second bump 50. With this arrangement, even when the semiconductor device 1 is used in a three-dimensional stack package with surface-mounted components, such as a capacitor and an inductor, each of which is thicker than the semiconductor chip 10, a difference in thickness between the semiconductor device 1 and the surface-mounted components can be suppressed, and additional components or the like for adjusting the above difference in thickness can be avoided.

The semiconductor device 1 may be used as the surface-mounted component. In this case, a relatively inexpensive component for surface-mounted components can be used instead of a mounting component for a flip chip.

With use of the metal plate 80 having a size that enables multiple semiconductor devices 1 to be formed, multiple semiconductor chips 10 are fixed on the metal plate 80, and then the semiconductor chips 10 may be divided into individual pieces after the first solder ball 71 and the second solder ball 72 are formed.

### [Example of Using Semiconductor Device]

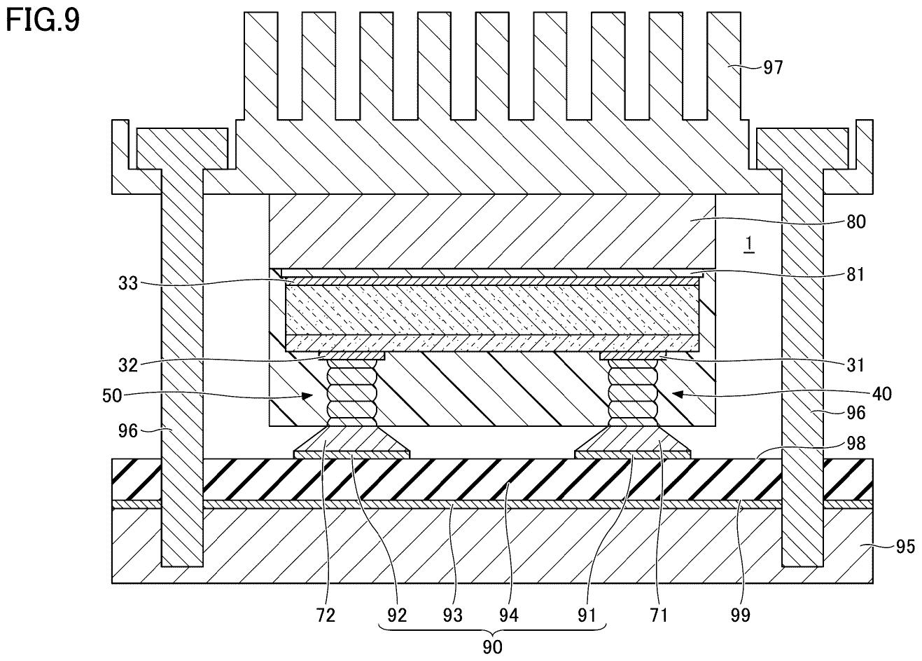

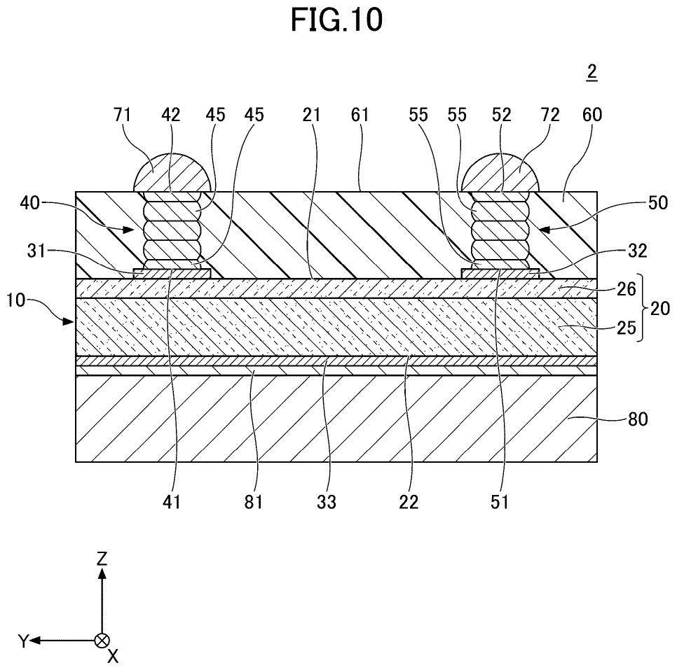

Hereinafter, an example of using the semiconductor device 1 according to the first embodiment will be described. FIG. 9 is a cross-sectional view showing the example of using the semiconductor device according to the first embodiment.

The semiconductor device 1 is mounted on a mounting substrate 90, for example, as shown in FIG. 9. The mounting substrate 90 is, for example, a printed wiring board or a ceramic substrate. The mounting substrate 90 includes a substrate 94, a wiring 91, a wiring 92, and a bonding layer 93. The substrate 94 has a sixth main surface 98 and a seventh main surface 99 opposite the sixth main surface 98. The wirings 91 and 92 are provided on the sixth main surface 98, and the bonding layer 93 is provided on the seventh main surface 99. Through reflow, the first solder ball 71 is coupled to the wiring 91, and the second solder ball 72 is coupled to the wiring 92. The wiring 91 is electrically coupled to the gate electrodes 36 (see FIG. 1) through the first solder ball 71, the first bump 40, and the gate pad 31. The wiring 92 is electrically coupled to the drain electrodes 37 (see FIG. 1) through the second solder ball 72, the second bump 50, and the drain pad 32.

The mounting substrate 90 is bonded to a metal housing 95 by the bonding layer 93. The bonding layer 93 may be a conductive layer. Conductive heat dissipation fins 97 are mounted on the metal plate 80. The heat dissipation fins 97 are fixed to the metal housing 95 by a plurality of conductive fixing screws 96. When the metal housing 95 is grounded, a ground potential is applied to the source electrodes 38 (see FIG. 1) through the fixing screws 96, the heat dissipation fins 97, the metal plate 80, the conductive adhesive 81, and the source pad 33.

### Second Embodiment

Hereinafter, a second embodiment will be described. The second embodiment mainly differs from the first embodiment in a dimensional relationship between the semiconductor chip 10 and the metal plate 80.

### [Configuration of Semiconductor Device]

The configuration of the semiconductor device according to the second embodiment will be described below. FIG. 10 is a cross-sectional view showing the semiconductor device according to the second embodiment.

In the semiconductor device 1 according to the first embodiment, an outer edge of the semiconductor chip 10 is located inside an outer edge of the metal plate 80 in a plan view viewed in a direction perpendicular to the fifth surface 61 of the insulating resin layer 60. On the other hand, in a semiconductor device 2 according to the second embodiment, the outer edge of the semiconductor chip 10 is aligned with the outer edge of the metal plate 80 in a plan view. In addition, an outer edge of the conductive adhesive 81 is aligned with the outer edge of the semiconductor chip 10 and the outer edge of the metal plate 80 in a plan view. The side surface of the substrate 20 and the side surface of the conductive adhesive 81 are not covered with the insulating resin layer 60, and are exposed from the insulating resin layer 60.

The other configurations in the second embodiment are the same as those in the first embodiment. The second embodiment also provides the same effects as described in the first embodiment.

### [Method for Manufacturing Semiconductor Device]

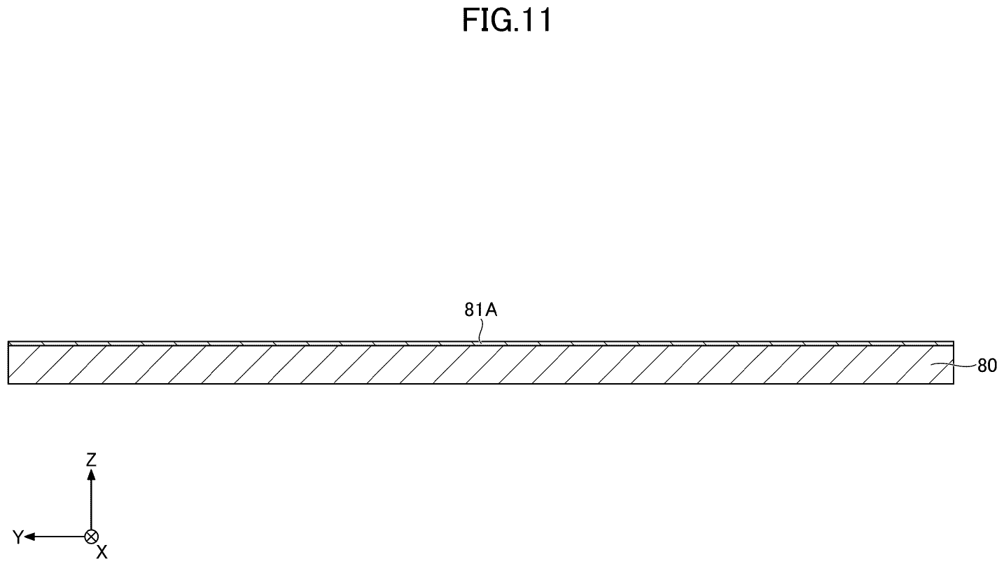

Hereinafter, a method for manufacturing the semiconductor device 2 according to the second embodiment will be described. FIGS. 11 to 17 are cross-sectional views showing the method for manufacturing the semiconductor device according to the second embodiment.

When the semiconductor device 2 according to the second embodiment is manufactured, a large-sized substrate 20 (wafer) from which semiconductor chips 10 are to be obtained is prepared. A gate pad 31, a drain pad 32, and a source pad 33 are formed on the substrate 20. Further, the metal plate 80 having a size corresponding to the substrate 20 is prepared. Then, as shown in FIG. 11, an Ag paste 81A is applied to the upper surface of the metal plate 80.

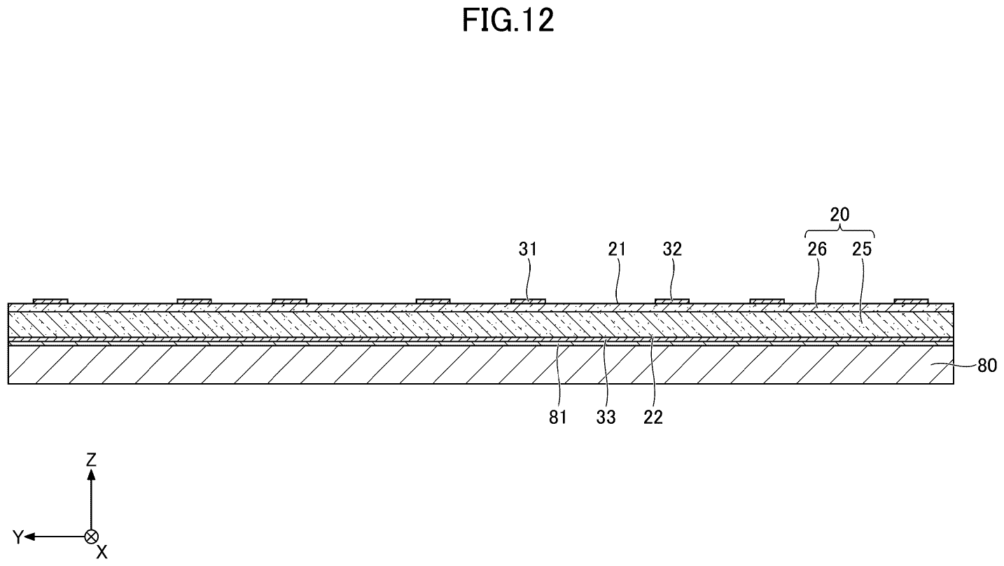

Next, as shown in FIG. 12, the substrate 20 is placed on the metal plate 80 such that the source pad 33 is in contact with the Ag paste 81A. Then, the Ag paste 81A is fired to form a conductive adhesive 81 from the Ag paste 81A, and the substrate 20 is fixed to the metal plate 80 with the conductive adhesive 81.

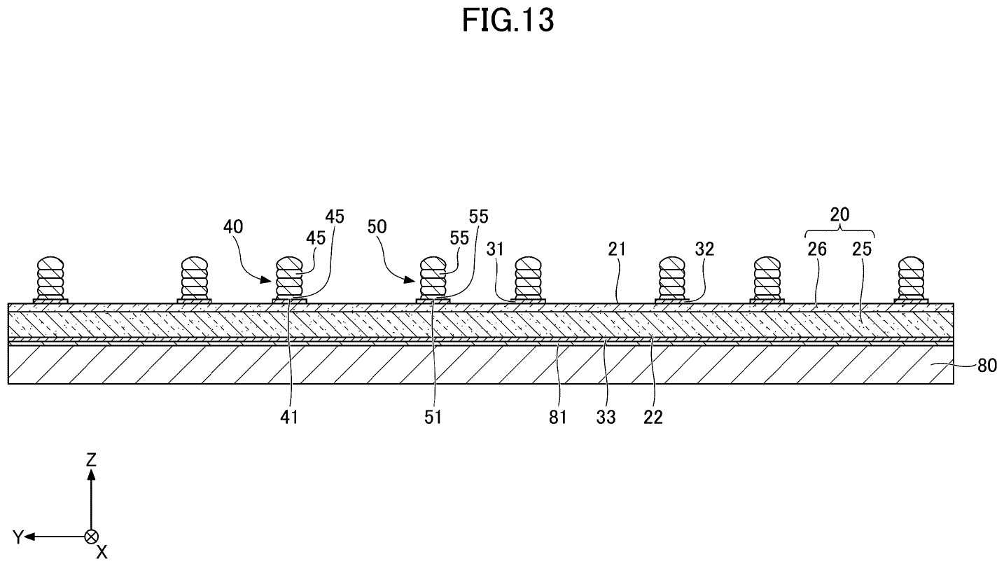

Next, as shown in FIG. 13, the first bumps 40 are formed on the gate pad 31, and the second bumps 50 are formed on the drain pad 32. In forming the first bump 40, first stud bumps 45 are stacked on the gate pad 31, and also, in forming the second bump 50, second stud bumps 55 are stacked on the drain pad 32. The first bumps 40 and the second bumps 50 are each formed to be higher than the final height. The first bump 40 has a first surface 41 in contact with the gate pad 31, and the second bump 50 has a third surface 51 in contact with the drain pad 32.

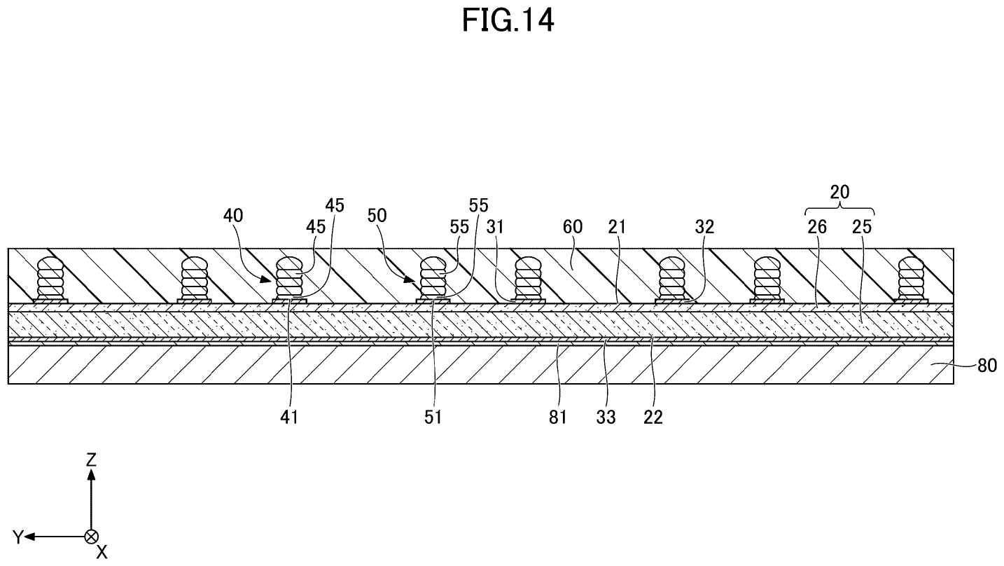

Next, as shown in FIG. 14, the insulating resin layer 60 is formed so as to cover the substrate 20, the gate pad 31, the drain pad 32, the first bumps 40, and the second bumps 50. The insulating resin layer 60 is formed to be thicker than a final thickness.

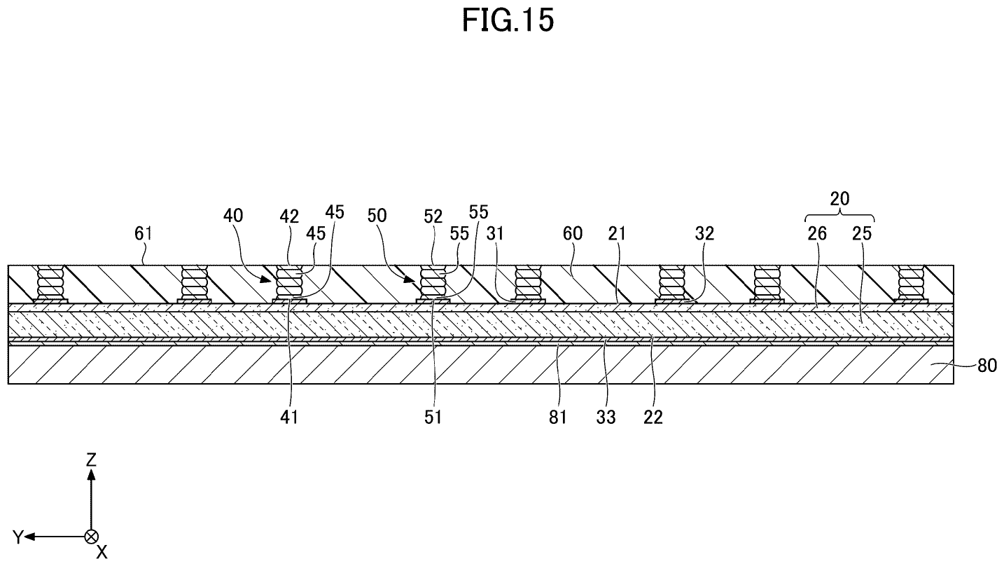

Next, as shown in FIG. 15, the insulating resin layer 60, the first bumps 40, and the second bumps 50 are grinded, so that heights of the first bumps 40 and the second bumps 50 are used as final heights, and the thickness of the insulating resin layer 60 is used as the final thickness. After grinding, the first bump 40 has a second surface 42 opposite the first surface 41, and the second bump 50 has a fourth surface 52 opposite the third surface 51.

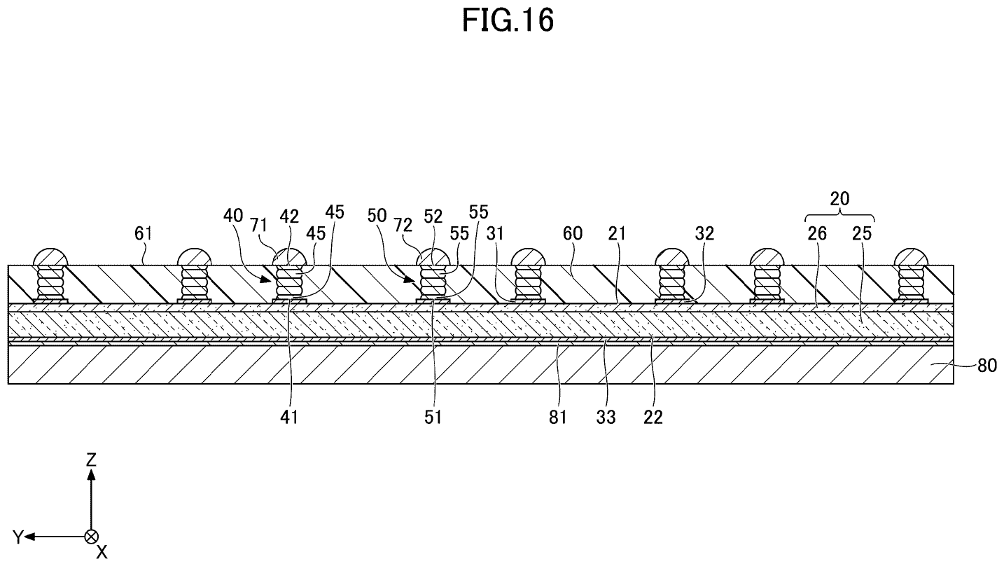

Next, as shown in FIG. 16, the first solder ball 71 is formed on the insulating resin layer 60 so as to be in contact with the second surface 42 of the first bump 40, and the second solder ball 72 is formed on the insulating resin layer 60 so as to be in contact with the fourth surface 52 of the second bump 50.

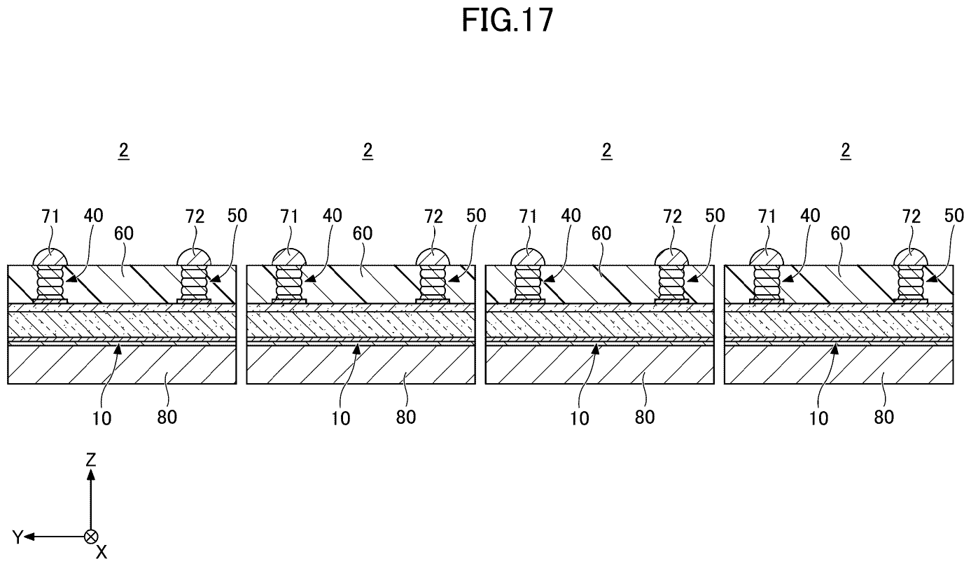

Next, as shown in FIG. 17, the resulting object is divided into individual laminated structures each of which includes the metal plate 80, the substrate 20, the insulating resin layer 60, and the like.

With this approach, the semiconductor device 2 according to the second embodiment can be manufactured.

### Third Embodiment

Hereinafter, a third embodiment will be described. The third embodiment relates to a semiconductor module with the semiconductor device 1 according to the first embodiment.

### [Configuration of Semiconductor Module]

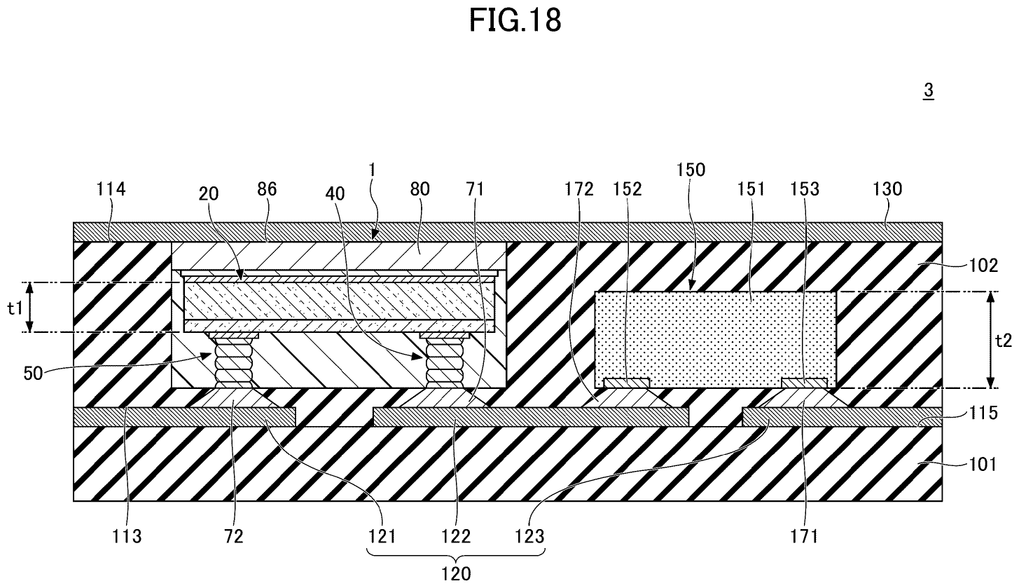

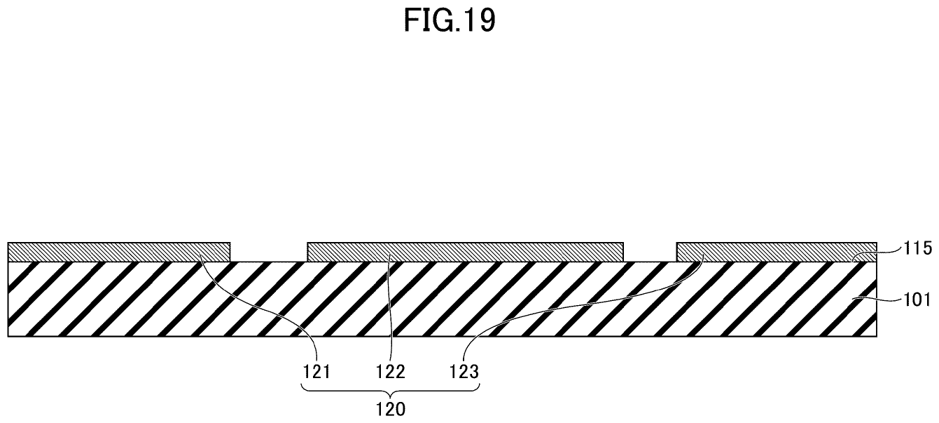

The configuration of the semiconductor module according to the third embodiment will be described. FIG. 18 is a cross-sectional view showing the semiconductor module according to the third embodiment.

The semiconductor module 3 according to the third embodiment includes insulating layers 101 and 102, a wiring layer 120, a conductive layer 130, the semiconductor device 1, and an electronic component 150.

An insulating layer 102 has a third main surface 113 and a fourth main surface 114 opposite the third main surface 113. The wiring layer 120 is provided on the third main surface 113. The wiring layer 120 includes wirings 121, 122, and 123. A wiring 122 is provided between a wiring 121 and a wiring 123. The insulating layer 101 covers the wiring layer 120. The insulating layer 101 has a fifth main surface 115 opposite the third main surface 113. The fifth main surface 115 is in contact with the insulating layer 102 and the wiring layer 120.

The semiconductor device 1 is provided in the insulating layer 102 and is connected to the wiring 121 and the wiring 122. Through reflow, the first solder ball 71 is connected to the wiring 122, and the second solder ball 72 is connected to the wiring 121. The wirings 121 and 122 are examples of a first wiring.

The electronic component 150 is, for example, a surface-mounted component, and includes a main body 151 and external electrodes 152 and 153. The electronic component 150 includes, for example, a capacitor, an inductor, or a resistor. The external electrode 152 is connected to the wiring 122 by a solder material 172, and the external electrode 153 is connected to the wiring 123 by a solder material 171. The semiconductor device 1 and the electronic component 150 are electrically connected to each other via the wiring 122. A first thickness t1 of the substrate 20 may be less than a second thickness t2 of the electronic component 150. The wiring 122 and the wiring 123 are examples of a second wiring. The wiring 122 can function as a first wiring and a second wiring.

The metal plate 80 of the semiconductor device 1 has the sixth surface 86 that is flush with the fourth main surface 114, and the metal plate 80 is exposed from the fourth main surface 114. The conductive layer 130 is in contact with the metal plate 80 and is electrically connected to the metal plate 80. For example, a ground potential is applied to the conductive layer 130. The conductive layer 130 overlaps the electronic component 150 in a plan view viewed in a direction perpendicular to the fourth main surface 114. In a plan view, an outer edge of the electronic component 150 is located inside an outer edge of the conductive layer 130. The insulating layer 102 is provided between the conductive layer 130 and the electronic component 150, and the conductive layer 130 and the electronic component 150 are separated from each other by the insulating layer 102. The metal plate 80 is an example of a conductive material.

The wiring layer 120 and the conductive layer 130 are, for example, copper layers. The material of the insulating layer 101 and the material of the insulating layer 102 are the same as the material of the insulating resin layer 60.

### [Method for Manufacturing Semiconductor Module]

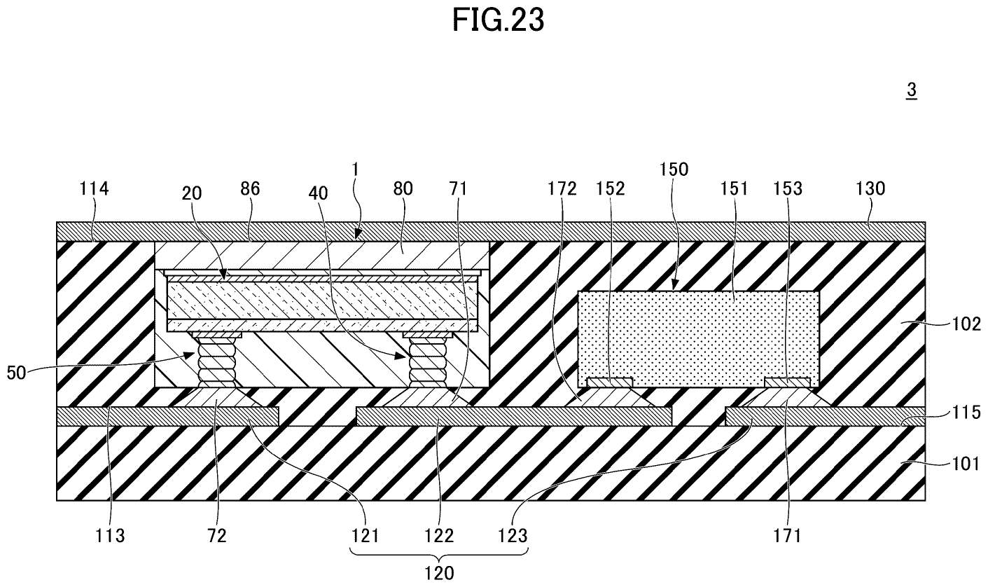

Hereinafter, a method for manufacturing the semiconductor module 3 according to the third embodiment will be described. FIGS. 19 to 23 are cross-sectional views illustrating the method for manufacturing the semiconductor module according to the third embodiment.

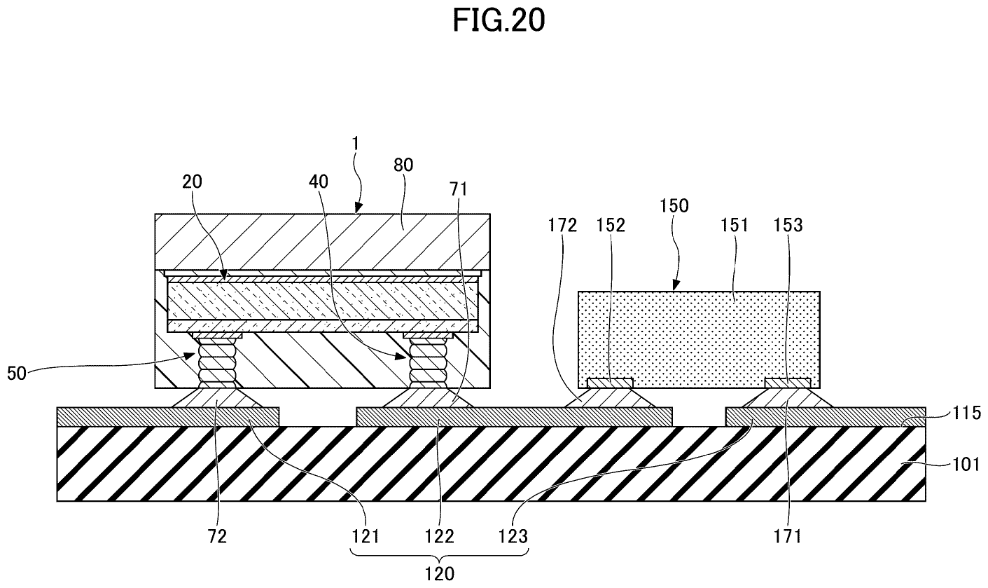

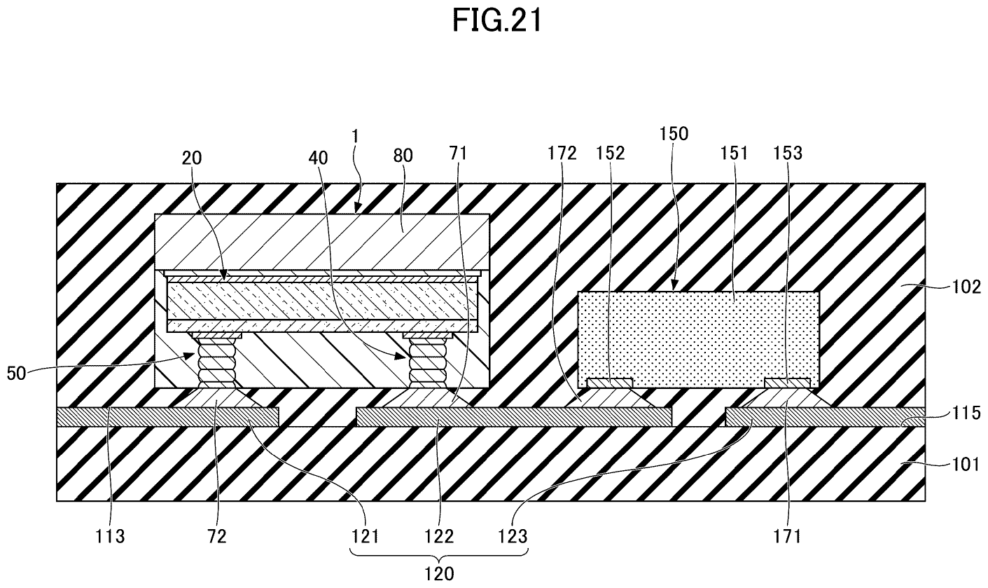

As shown in FIG. 19, the wiring layer 120 is first formed on the fifth main surface 115 of the insulating layer 101. The wiring layer 120 can be formed by, for example, plating. Then, as shown in FIG. 20, the semiconductor device 1 and the electronic component 150 are provided above the wiring layer 120. For example, then, as shown in FIG. 21, the insulating layer 102 is formed on the fifth main surface 115 so as to cover the wiring layer 120, the semiconductor device 1, and the electronic component 150. The insulating layer 102 is formed to have a thickness greater than the final thickness.

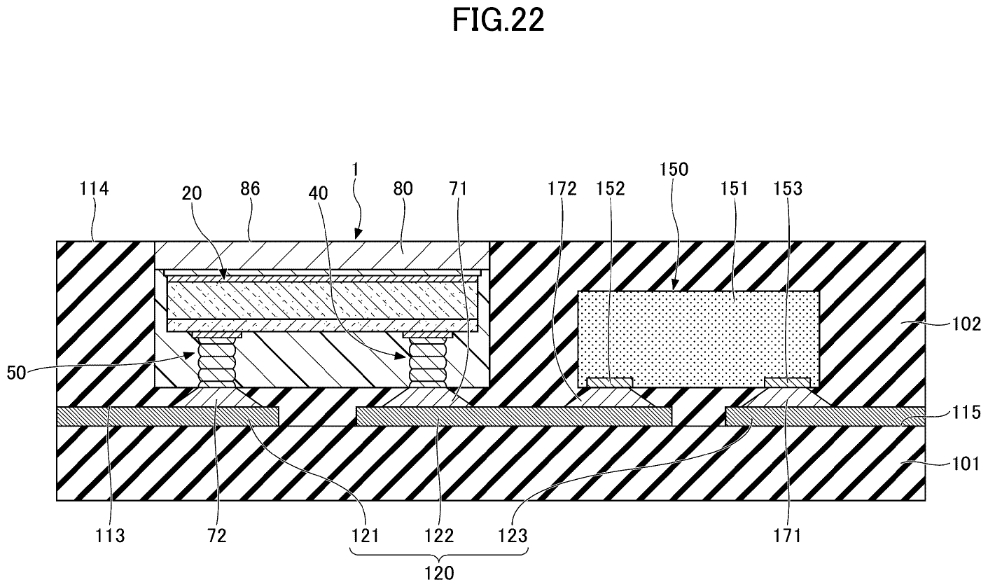

Next, as shown in FIG. 22, the insulating layer 102 and the metal plate 80 of the semiconductor device 1 are grinded, and the resulting thicknesses of the semiconductor device 1 and the insulating layer 102 are used as final thicknesses. The sixth surface 86 of the metal plate 80 and the fourth main surface 114 of the insulating layer 102 may be flush with each other. Next, the conductive layer 130 is formed on the insulating layer 102 and the metal plate 80. The conductive layer 130 can be formed by, for example, plating.

With this approach, the semiconductor module 3 according to the third embodiment can be manufactured.

The semiconductor module 3 includes the semiconductor device 1. In this arrangement, the semiconductor module 3 can be made compact while adjusting the thickness of the semiconductor device 1. Even when the first thickness t1 of the substrate 20 of the semiconductor device 1 is less than the second thickness t2 of the electronic component 150, the metal plate 80 can be exposed from the fourth main surface 114 of the insulating layer 102 by adjusting heights of the first stud bumps 45 and the second stud bumps 55. The metal plate 80 can be brought into contact with and electrically connected to the conductive layer 130 that is provided on the fourth main surface. The electronic component 150 can be separated from the conductive layer 130 by the insulating layer 102. In manufacturing, the fourth main surface 114 and the sixth surface 86 can be made flush with each other by grinding.

### Fourth Embodiment

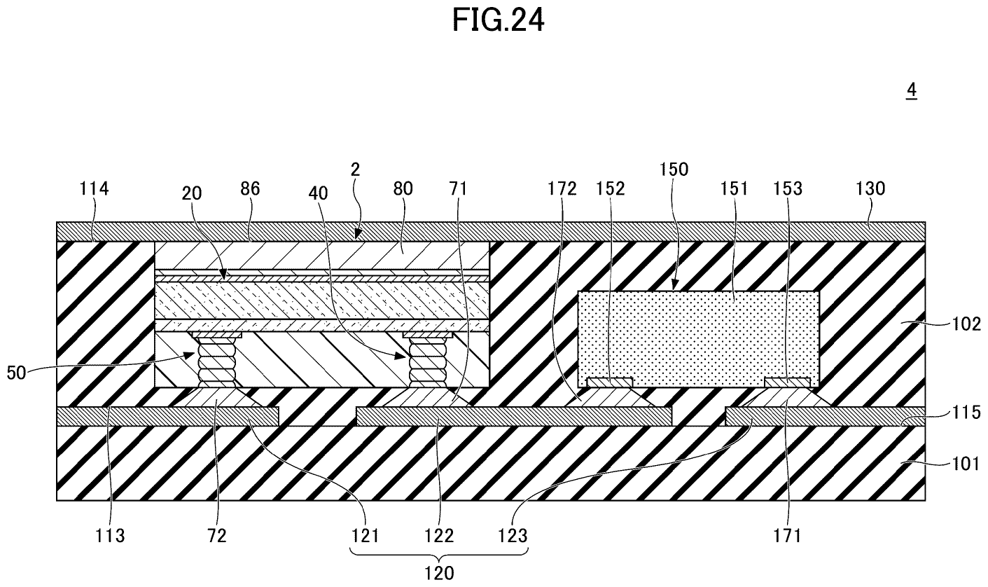

Hereinafter, a fourth embodiment will be described. FIG. 24 is a cross-sectional view showing the semiconductor module according to the fourth embodiment. A semiconductor module 4 according to the fourth embodiment differs from the third embodiment in that the semiconductor module 4 includes the semiconductor device 2 according to the second embodiment instead of the semiconductor device 1 according to the first embodiment. The other configurations in the fourth embodiment are the same as described in the third embodiment. The fourth embodiment also provides the same effects as described in the third embodiment.

Although the embodiments are described above in detail, the present disclosure is not limited to specific embodiments, and various modifications and changes can be made within the scope described in the present disclosure.

What is claimed is:

1. A semiconductor device comprising:
a substrate having a first main surface and a second main surface opposite the first main surface;
a gate pad provided on the first main surface;
a drain pad provided on the first main surface;
a source pad provided on the second main surface;
a first bump provided on the gate pad, and including a plurality of first stud bumps stacked over one another;
a second bump provided on the drain pad, and including a plurality of second stud bumps stacked over one another; and
an insulating resin layer provided around the first bump and the second bump.

2. The semiconductor device according to claim 1,
wherein the first bump has (i) a first surface in contact with the gate pad and (ii) a second surface opposite the first surface,
wherein the second bump has (i) a third surface in contact with the drain pad and (ii) a fourth surface opposite the third surface, and
wherein the insulating resin layer has a fifth surface that is continuous with the second surface and the fourth surface.

3. The semiconductor device according to claim 2, wherein the second surface, the fourth surface, and the fifth surface are flush with one another.

4. The semiconductor device according to claim 2, further comprising:
a first solder ball provided on the second surface; and
a second solder ball provided on the fourth surface.

5. The semiconductor device according to claim 2, wherein each of the second surface and the fourth surface has an arithmetic mean roughness of greater than or equal to 0.03 μm and less than or equal to 0.10 μm.

6. The semiconductor device according to claim 1, further comprising:
a metal plate bonded to the source pad, the metal plate being electrically coupled to the source pad.

7. The semiconductor device according to claim 1, wherein the substrate includes a nitride semiconductor layer.

8. A semiconductor module comprising:
an insulating layer having a third main surface and a fourth main surface opposite the third main surface;
a wiring layer including a first wiring and a second wiring, and being provided on the third main surface of the insulating layer;
the semiconductor device of claim 1, the semiconductor device being provided in the insulating layer and being coupled to the first wiring; and
an electronic component provided in the insulating layer, and being coupled to the second wiring,
wherein the semiconductor device includes a conductive material electrically coupled to the source pad, the conductor material being exposed from the fourth main surface of the insulating layer.

9. The semiconductor module according to claim 8, wherein a first thickness of the substrate is less than a second thickness of the electronic component.

10. The semiconductor module according to claim 8, wherein the conductive material has a sixth surface flush with the fourth main surface.

11. The semiconductor module according to claim 8, further comprising:
a conductive layer provided on the fourth main surface of the insulating layer, and being in contact with the conductive material,
wherein the conductive layer and the electronic component are separated from each other by the insulating layer.

12. A method for manufacturing a semiconductor device, the method comprising:
providing a semiconductor chip including a substrate, a gate pad, a drain pad, and a source pad, the semiconductor chip including
the substrate having a first main surface and a second main surface opposite the first main surface,
the gate pad and the drain pad that are provided on the first main surface, and
the source pad provided on the second main surface;
forming a first bump on the gate pad;
forming a second bump on the drain pad;
forming an insulating resin layer around the first bump and the second bump; and
grinding the insulating resin layer, the first bump, and the second bump,
wherein the first bump includes a plurality of first stud bumps stacked over one another, and
wherein the second bump includes a plurality of second stud bumps stacked over one another.
